(19) United States
(12) Patent Application Publication
(10) Pub. No.: US 2025/0363001 A1
(43) Pub. Date: Nov. 27, 2025

(54) SEMICONDUCTOR MEMORY DEVICE SUPPLYING REAL-TIME FAULT FLAG AND FAULT FLAG SUPPLYING METHOD THEREOF

(71) Applicant: SAMSUNG ELECTRONICS CO., LTD., Suwon-si (KR)

(72) Inventors: Donggeun Lee, Suwon-si (KR); Sung-Rae Kim, Suwon-si (KR); Ki-Heung Kim, Suwon-si (KR); Jinyong Choi, Suwon-si (KR)

(21) Appl. No.: 19/186,330

(22) Filed: Apr. 22, 2025

(30) Foreign Application Priority Data
May 22, 2024 (KR) 10-2024-0066777
Jan. 6, 2025 (KR) 10-2025-0001823

(51) Int. Cl. G06F 11/10

(52) U.S. Cl. CPC G06F 11/1044

(57) ABSTRACT

A method for providing a fault flag of a semiconductor memory device comprises changing the operation mode of the semiconductor memory device from a meta mode to a Reliability, Availability and Serviceability (RAS) mode, collecting a fault flag of the semiconductor memory device, inserting the fault flag into a metadata field of a data packet of the semiconductor memory device, and outputting the data packet into which the fault flag is inserted.

### CROSS-REFERENCE TO RELATED APPLICATIONS

This application claims priority to Korean Patent Application No. 10-2024-0066777 filed on May 22, 2024, and Korean Patent Application No. 10-2025-0001823 filed on Jan. 6, 2025, in the Korean Intellectual Property Office, the disclosures of which are incorporated by reference herein in their entireties.

### BACKGROUND

Recently, various mobile devices or electronic devices, such as smartphones, desktop computers, laptop computers, tablet PCs, and wearable devices, are widely used. These electronic devices usually include semiconductor memory devices for storing data. As an example of a semiconductor memory device, dynamic random access memory DRAM, which is a volatile memory, stores data by the charge stored in a capacitor.

Meanwhile, the Low Power Double Data Rate 6 (LPDDR6) specification is being proposed for high-performance, low-power memory required for mobile devices and embedded systems. The LPDDR6 standard supports data transfer speeds of gigabits per second (Gbps), which are improved over the previous generation. In addition, LPDDR6 memory provides features that are ideal for power efficiency, high-resolution video streaming, gaming, artificial intelligence AI, and machine learning ML applications. In addition, LPDDR6 memory can provide higher reliability by including improved error correction code ECC to maintain data integrity, and can contribute to improving system stability. Based on these features, LPDDR6 memory is expected to play a significant role in providing better performance and power efficiency in next-generation mobile devices and embedded systems.

### SUMMARY

In general, the present disclosure is directed toward a semiconductor memory device providing a real-time fault flag and a method for providing the fault flag thereof.

According to some implementations, the present disclosure is directed to a method for providing a fault flag of a semiconductor memory device comprising, changing the operation mode of the semiconductor memory device from a meta mode to a Reliability, Availability and Serviceability (RAS) mode, collecting a fault flag of the semiconductor memory device, inserting the fault flag into a metadata field of a data packet of the semiconductor memory device, and outputting the data packet into which the fault flag is inserted.

According to some implementations, the present disclosure is directed to a semiconductor memory device comprising, a memory cell array storing data, a mode register set configured to be written setting of a meta mode or a Reliability, Availability, Serviceability (RAS) mode, a fault flag register configured to store a fault flag generated in the semiconductor memory device, a mode controller configured to assign the fault flag to a metadata field of a data packet output according to the setting of the RAS mode, and an input/output circuit configured to output the data packet with the fault flag inserted in the metadata field.

According to some implementations, the present disclosure is directed to a method for providing a fault flag of a semiconductor memory device comprising, activating, by a memory controller, a Reliability, Availability and Serviceability (RAS) mode of the semiconductor memory device, activating, by a memory controller, a link Error Correcting Code (ECC) mode of the semiconductor memory device, generating, by the semiconductor memory device, a fault flag and link ECC parity in response to the activation of the RAS mode and the link ECC mode, inserting the fault flag into a metadata field of a data packet of the semiconductor memory device, and inserting the link ECC parity into a link ECC field of the data packet.

### BRIEF DESCRIPTION OF THE FIGURES

Example implementations will be more clearly understood from the following detailed description, taken in conjunction with the accompanying drawings.

FIG. 1 is a block diagram showing an example of a memory system according to some implementations.

FIG. 2 is a block diagram showing the memory device of FIG. 1 according to some implementations.

FIG. 3 is a table briefly showing examples of functions of the meta mode and RAS mode of the memory device of FIG. 2 according to some implementations.

FIG. 4 is a table showing an example of a data packet according to some implementations.

FIG. 5 is a table briefly showing examples of types of metadata fields and fault flags corresponding to them in the RAS mode according to some implementations.

FIG. 6 is a table showing an example of a method of transmitting a fault flag using a metadata field in the RAS mode according to some implementations.

FIG. 7 is a table showing an example of a method of processing a fault flag received in the RAS mode according to some implementations.

FIG. 8 is a diagram showing an example of a method of setting a RAS mode and transmitting a fault flag in a memory system according to some implementations.

FIG. 9 is a table showing examples of a metadata field (M-field) and a link ECC field (L-field) when link ECC is activated in the RAS mode according to some implementations.

FIG. 10 is a diagram showing an example of a method for setting a RAS mode and transmitting a fault flag in a memory system according to some implementations.

FIG. 11 is a block diagram showing an example of a mobile system according to some implementations.

FIG. 12 is a cross-sectional diagram showing an example of a memory system according to some implementations.

### DETAILED DESCRIPTION

Hereinafter, example implementations will be explained in detail with reference to the accompanying drawings.

It is to be understood that both the foregoing general description and the following detailed description are exemplary, and it is to be considered that an additional description of the claimed invention is provided. Reference signs are indicated in detail in preferred embodiments of the present invention, examples of which are indicated in the reference drawings. Wherever possible, the same reference numbers are used in the description and drawings to refer to the same or like parts.

Hereinafter, DRAM will be used as an example implementations of a semiconductor memory device to explain the features and functions of the present invention. However, the present disclosure is not limited thereto.

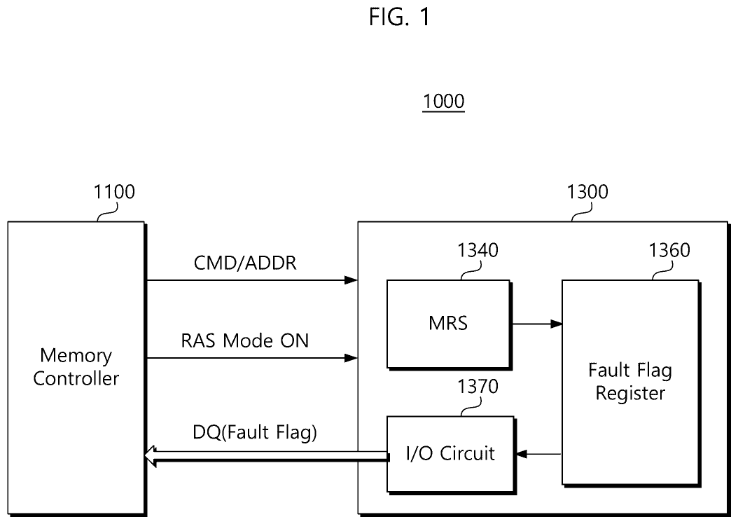

FIG. 1 is a block diagram showing an example of a memory system according to some implementations. In FIG. 1, the memory system 1000 includes a memory controller 1100 and a memory device 1300. The memory controller 1100 can receive a fault flag in real time using a Reliability, Availability, and Serviceability (hereinafter, RAS) mode of the memory device 1300. At this time, the fault flag can be provided to the memory controller 1100 through the data DQ pin.

The memory controller 1100 can perform an access operation to write data to the memory device 1300 or read data stored in the memory device 1300. The memory controller 1100 can generate a command CM D and an address ADDR for writing data to the memory device 1300 or reading data stored in the memory device 1300. The memory controller 1100 may be at least one of a chipset for controlling the memory device 1300, a system on chip SoC, such as a mobile Application Processor (hereinafter, AP), a CPU, and a GPU.

For example, the memory controller 1100 may activate the RAS mode of the memory device 1300 to receive the fault flag in real time. The memory device 1300 may operate in a meta mode for performing initialization or setting, register configuration, training procedures, etc. Alternatively, the memory device 1300 may operate in the RAS mode supported for error detection or data integrity. In addition, when a link Error Correcting Code (ECC) mode is activated in the RAS mode activation state, all operations for signal integrity for data transmission and communication between the memory device 1300 and the memory controller 1100 are supported. The meta mode and the RAS mode are activated exclusively. In other words, the meta mode must be deactivated in order for the RAS mode to be activated.

The memory controller 1100 can receive the fault flag through the metadata field of the data DQ packet by disabling the meta mode and activating the RAS mode. The metadata field of the data DQ packet provided in the RAS mode includes the fault flag for one channel data packet (e.g., 288-bit). Accordingly, the memory controller 1100 in the RAS mode can check and correct or detect in real time whether there is an error or fault in the output channel data packet through the metadata field.

The memory device 1300 can select or change an operation mode, such as the meta mode, the RAS mode, and the link ECC mode, according to the control of the memory controller 1100. The memory device 1300 provides the metadata to the memory controller 1100 through the metadata field of the data DQ packet in the meta mode. On the other hand, the memory device 1300 provides the fault flag of a data DQ packet unit to the memory controller 1100 in real time through the metadata field of the data DQ packet in the RAS mode. At this time, if the link ECC mode is activated, the memory device 1300 can additionally provide a link ECC parity for the data packet in the RAS mode to the memory controller 1100. To this end, the memory device 1300 can include a mode set register 1340, a fault flag register 1360, and an input/output circuit 1370.

The mode set register 1340 can receive a mode switching request provided through a command/address CA. For example, if RAS mode activation is requested through a mode register write (hereinafter, MRW), the request is written to the mode set register 1340. Then, the meta mode will be deactivated and the RAS mode will be activated. Through this mode register write MRW, activation of the link ECC mode or other mode settings can be performed.

The fault flag register 1360 collects or stores fault flags in the RAS mode. The fault flags stored in the fault flag register 1360 can be inserted into the metadata field by type. For example, if the fault flag corresponds to the on-die ECC correctable (hereinafter, OD-ECC CE) flag, the corresponding flag in the fault flag register 1360 is assigned to a specific bit column in the metadata field. In addition, if the OD-ECC CE flag is assigned to three bits, the fault flag of one bit in the fault flag register 1360 can be repeatedly written to the metadata field with the same bit value three times. For example, if the OD-ECC CE flag stored in the fault flag register 1360 corresponds to logic ‘1’, ‘111’ may be repeatedly written to the three allocated metadata fields.

The input/output circuit 1370 outputs read data Dout as a data DQ packet using a clock signal or a data strobe signal DQS. The data DQ packet may be transmitted to the memory controller 1100 in synchronization with the data strobe signal DQS. For example, the input/output circuit 1370 may output or receive data in units of one channel data packet (e.g., 288-bit). In this case, 256 bits in one channel data packet may be user data, and the remaining 32 bits may be the metadata field or the link ECC data field of the present invention.

The memory device 1300 may be implemented as a volatile memory device. The volatile memory device may be implemented as a Random Access Memory (RAM), a Dynamic RAM (DRAM), or a Static RAM (SRAM), but the present disclosure is not limited thereto. For example, the memory device 1300 may correspond to a Double Data Rate Synchronous Dynamic Random Access Memory (DDR SDRAM), an LPDDR4 SDRAM, an LPDDR5 SDRAM, or an LPDDR6 SDRAM, a Graphics Double Data Rate (GDDR) SDRAM, an Rambus Dynamic Random Access Memory (RDRAM), etc. In some implementations, the memory device 1300 may be implemented as a high-bandwidth memory HBM. However, the present disclosure is not limited thereto, and the memory device 1300 may include a nonvolatile memory device. However, in the present disclosure, the memory device 1300 will be described as an example of a volatile memory.

The memory system 1000 may be implemented to be included in a personal computer PC or a mobile device. The mobile device may be implemented as a laptop computer, a mobile phone, a smart phone, a tablet PC, a Personal Digital Assistant (PDA), an Enterprise Digital Assistant (EDA), a digital still camera, a digital video camera, a Portable Multimedia Player (PMP), a Personal Navigation Device or Portable Navigation Device (PND), a handheld game console, a Mobile Internet Device (MID), a wearable computer, an Internet of Things (IoT) device, an Internet of Everything (IoE) device, or a drone.

According to some implementations, the memory device 1300 can provide the fault flag to the memory controller 1100 in real time through the metadata field of the data DQ packet in the RAS mode. Accordingly, compared to the case where the fault flag is provided asynchronously through a separate pin, it is possible to identify the type of error provided through the metadata field of the corresponding data packet in real time and perform rapid processing. In addition, by utilizing the link ECC mode, it is possible to detect or correct errors in the fault flag itself. Accordingly, the memory system 1000 according to the embodiment of the present invention can significantly reduce overhead from the RAS perspective.

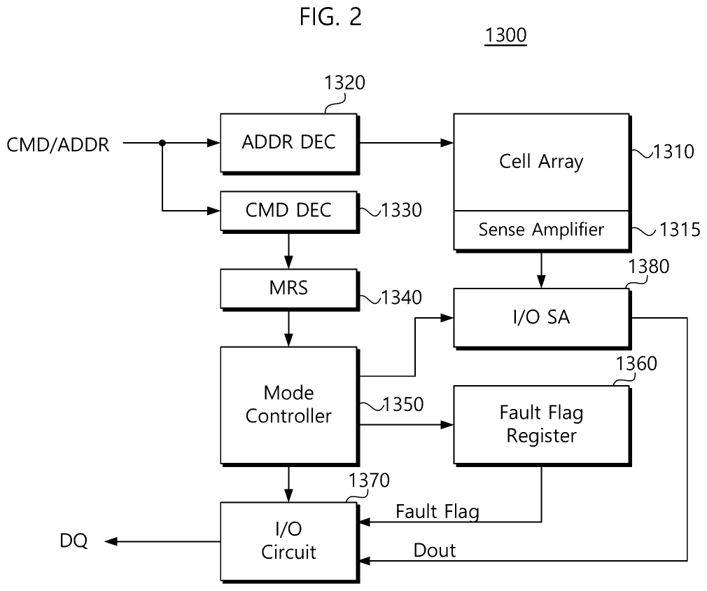

FIG. 2 is a block diagram showing the memory device of FIG. 1 according to some implementations. In FIG. 2, the memory device 1300 may include a cell array 1310, a sense amplifier 1315, an address decoder 1320, a command decoder 1330, a mode register set 1340, a mode controller 1350, a fault flag register 1360, an input/output circuit 1370, and an input/output sense amplifier 1380.

The cell array 1310 includes a plurality of memory cells. Write data received through the input/output sense amplifier 1380 may be written to the plurality of memory cells by the sense amplifier 1315. And the data written to the memory cell is selected by the command CM D and address ADDR of the memory controller 1100 and sensed by the sense amplifier 1315. Data sensed by the sense amplifier 1315 may be transmitted to the input/output sense amplifier 1380 and then transmitted to the input/output circuit 1370.

The address decoder 1320 receives the address A DDR of the memory cell being accessed. When data is stored in the memory cell or data is read from the memory cell, the address ADDR may be transmitted to the cell array 1310 as a row and column address through the address decoder 1320.

The command decoder 1330 may access the mode register set 1340 for setting various modes and operations of the memory device 1300. The command decoder 1330 may identify the properties of the input command by referring to signals applied from the outside. For example, a general auto refresh operation is input through a combination of control signals (e.g., /RAS, /CAS, /WE).

Then, a refresh operation for the cell array 1310 can be triggered by the command decoder 1330. In addition, the command decoder 1330 can write data to the mode register set 1340 according to the command CM D and address A DDR provided externally. For example, the mode register write MRW for activating a RAS mode of the present invention is applied to the mode register set 1340 by the command decoder 1330.

The mode register set 1340 sets the internal mode registers in response to the MRS command and address ADDR for specifying the operation mode of the memory device 1300. The mode register set 1340 of the present invention may be configured to set modes such as meta mode, RAS mode, and link ECC mode. In the meta mode, both user data and metadata are stored in the memory device 1300, and during a read operation, the metadata can be provided to the memory controller 1100 through the metadata field. The metadata may be data used for purposes such as improving the performance of the memory device or enhancing security. M ode changes or settings such as the RAS mode and the link ECC mode can be made by writing the mode register set 1340 by the MRS command and the address ADDR.

The mode controller 1350 can control the memory device 1300 for operation in the selected mode. For example, the mode controller 1350 can control the input/output circuit 1370 to allocate metadata to the metadata field in the meta mode. In the RAS mode, the mode controller 1350 will allocate the fault flag stored in the fault flag register 1360 to the metadata field. In the link ECC mode, the mode controller 1350 can control the input/output circuit 1370 to assign link ECC parity to the link ECC field.

The fault flag register 1360 stores the fault flag collected in the RAS mode. The fault flag register 1360 can transfer the fault flag to the input/output circuit 1370 by type. For example, if the fault flag corresponds to the on-die ECC correctable (OD-ECC CE) flag, the mode controller 1350 assigns the OD-ECC CE flag provided from the fault flag register 1360 to a specific bit column of the metadata field. In addition, if the OD-ECC CE flag is assigned to three bits in the metadata field, the mode controller 1350 can repeatedly write the same flag bit to each of the three bits. For example, if the OD-ECC CE flag corresponds to logic ‘1’, the mode controller 1350 can write the flag bit of logic ‘1’ as ‘111’ in the three allocated metadata fields.

The input/output circuit 1370 outputs read data Dout as a data DQ packet using a clock signal or a data strobe signal DQS. The data DQ packet can be transmitted to the memory controller 1100 in synchronization with the data strobe signal DQS. For example, the input/output circuit 1370 can output or receive data in units of one channel data packet (e.g., 288-bit). In this case, 256 bits in one channel data packet can be user data, and the remaining 32-bits can be a metadata field or a link ECC field of the present invention.

In some implementations, the memory cell included in the cell array 1310 may be a non-volatile memory cell, and the memory device 1300 may be, for non-limiting examples, a non-volatile memory such as an Electrically Erasable Programmable Read-Only Memory (EEPROM), a flash memory, a Phase Change Random Access Memory PRAM), a Resistance Random Access Memory (RRAM), a Nano Floating Gate Memory (NFGM), a Polymer Random Access Memory (PoRAM), a Magnetic Random Access Memory (M RAM), a Ferroelectric Random Access Memory (FRAM), and the like. Hereinafter, the memory device 1300 is described as being a DRAM, but it will be well understood that the technical idea of the present disclosure is not limited thereto.

As described above, the memory device 1300 can provide the fault flag to the memory controller 1100 in real time through the metadata field of the data DQ packet in the RAS mode.

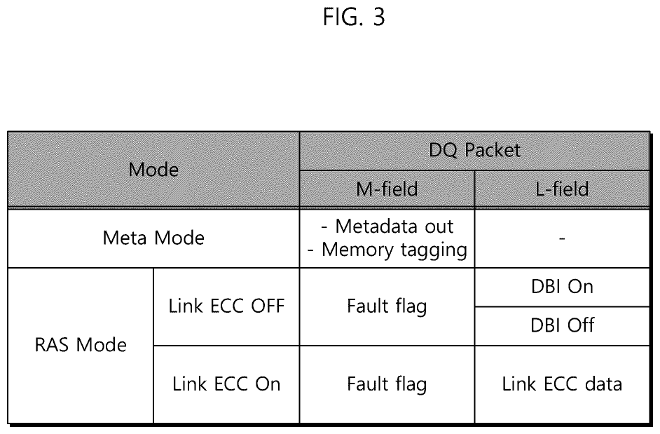

FIG. 3 is a table briefly showing examples of functions of the meta mode and RAS mode of the memory device of FIG. 2 according to some implementations. In FIG. 3, the memory device 1300 may use the metadata field (hereinafter, M-field) in the RAS mode as a channel for outputting various fault flags in real time.

In the meta mode, the metadata field (M-field) of the data packet is used for outputting the metadata stored in the memory device 1300. In addition, the metadata field (M-field) can be used as an area for memory tagging for the purpose of security, performance optimization, debugging, etc. The function of the metadata field (M-field) of the data DQ packet in the meta mode can be set in various ways depending on the user's purpose.

The RAS mode is divided into the link ECC off mode and the link ECC on mode. According to some implementations, regardless of whether the link ECC is on or off, a fault flag is inserted into the metadata field (M-field) in the RAS mode. In the link ECC off mode, data bus inversion DBI data for improving transmission power efficiency of the channel can be inserted into the link ECC field (L-field). And in the link ECC on mode, link ECC data for the entire data DQ packet can be inserted into the link ECC field (L-field).

As described above, the memory device 1300 provides the fault flag of the data DQ packet output through the metadata field (M-field) of the data DQ packet in real time to the memory controller 1100 in the RAS mode. At this time, when the link ECC mode is activated, the memory device 1300 can additionally provide link ECC data for data DQ packets in RAS mode to the memory controller 1100.

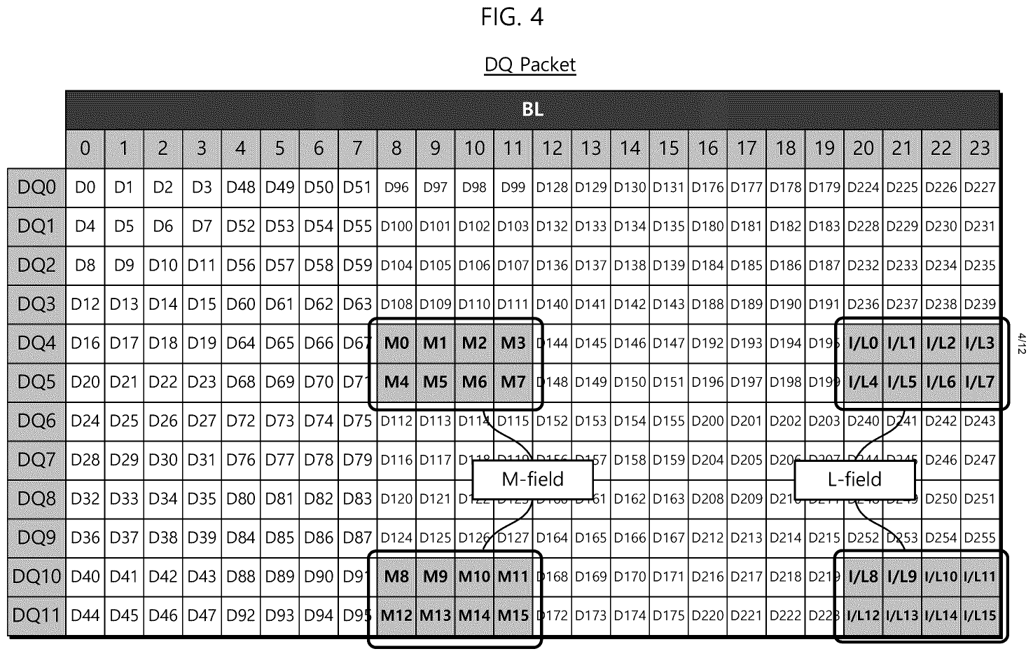

FIG. 4 is a table showing an example of a data DQ packet according to some implementations. In FIG. 4, a data DQ packet can have a bit size of 288-bits under 12-DQ pins (DQ0 to DQ11) and 24 burst lengths (BL0 to BL23). And out of the 288-bits, 256-bits can be used for transmission of normal data, and the remaining 32-bits can be used for transmission of non-data such as metadata or parity.

16-bit metadata M0 to M15 may be allocated to the metadata field (M-field) corresponding to the burst length (BL8, BL9, BL10, BL11) of the data DQ pins (DQ4, DQ5, DQ10, DQ11) of the data DQ packet. The memory device 1300 can output metadata stored in the cell array 1310 or generated internally through the metadata field (M-field) in the meta mode. On the other hand, the memory device 1300 can output the type of fault or other fault information occurring in the memory device 1300 to the outside in real time through the metadata field (M-field) in the RAS mode.

16-bit DBI or link ECC data (I/L0˜I/L15) can be allocated to the link ECC field (L-field) corresponding to the burst length (BL20, BL21, BL22, BL23) of the data DQ pins (DQ4, DQ5, DQ10, DQ11) of the data DQ packet. The memory device 1300 can provide DBI information or link ECC parity for the entire data DQ packet through the link ECC field (L-field) in the RAS mode. In the link ECC off mode of the RAS mode, data bus inversion DBI data (10 to 115) for channel transmission power efficiency can be inserted into the link ECC field (L-field). And in the link ECC on mode, link ECC parity (L0 to L15) for the data DQ packet can be inserted into the link ECC field (L-field).

The size of the above-described data DQ packet or the position of the metadata field (M-field) and the link ECC field (L-field) within the data DQ packet are merely exemplary, and it will be well understood that the technical idea of the present disclosure is not limited thereto.

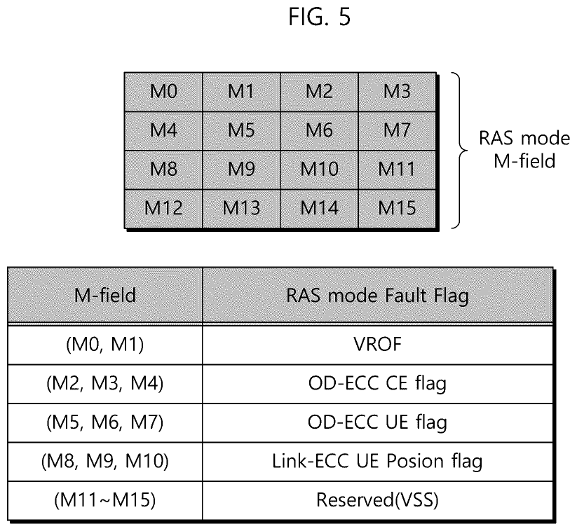

FIG. 5 is a table briefly showing examples of types of metadata fields and fault flags in the RAS mode according to some implementations. In FIG. 5, in the RAS mode, the metadata field (M-field) can be used to output information on faults occurring in real time within the memory device (1300, see FIG. 2).

In the RAS mode, among the 16-bit metadata M0 to M15, 2-bit metadata M0 and M1 may be used as a valid read operation flag VROF. That is, the valid read operation flag VROF may indicate whether the data output as a data DQ packet is valid for reading. For example, the memory device 1300 can output the valid read operation flag VROF as a logical value ‘11’ in the case of the data DQ packet output through a normal read operation.

In the RAS mode, among 16-bit metadata M0 to M15, 3-bit metadata M2, M3 and M4 can be used as a OD-ECC CE flag. That is, the OD-ECC CE flag is a flag indicating that an error exists in data output as a data DQ packet and that the error is correctable. The memory device 1300 transmits the OD-ECC CE flag using the 3-bit metadata M2, M3 and M4 when an error exists in a data DQ packet but is correctable. For example, the memory device 1300 can generate an OD-ECC CE flag as a logic ‘111’ and assign it to 3-bit metadata M2, M3 and M4.

In the RAS mode, among 16-bit metadata M0 to M15, 3-bit metadata M5, M6 and M7 may be used as a OD-ECC UE flag. That is, the OD-ECC UE flag is a flag indicating that there is an error in data output as a data DQ packet and that it is an uncorrectable error. The memory device 1300 transmits the OD-ECC UE flag using 3-bit metadata M5, M6 and M7 when an uncorrectable error exists in a data DQ packet. For example, the memory device 1300 may generate the OD-ECC UE flag as a logic ‘111’ and assign it to 3-bit metadata M5, M6 and M7.

In the RAS mode, among 16-bit metadata M0 to M15, 3-bit metadata M8, M9 and M10 may be used as a Link-ECC Uncorrectable Error (UE) Poison flag. That is, the Link-ECC UE Poison flag is transmitted to the memory controller 1100 to inform that an uncorrectable error exists in the data channel. When the Link-ECC UE Poison flag is received, the memory controller 1100 will stop data transmission in which a link error has occurred and perform processing at the system level. When an uncorrectable link error exists, the memory device 1300 transmits the Link-ECC UE Poison flag using 3-bit metadata M8, M9 and M10. The memory device 1300 may generate the Link-ECC UE Poison flag as a logic ‘111’ and assign it to the 3-bit metadata M8, M9 and M10.

In the RAS mode, the remaining metadata M11 to M15 among the 16-bit metadata M0 to M15 may be utilized as a reserved area. The reserved area can be used for various purposes or for allocating additional flags according to the user's request.

As described above, the memory device 1300 of the present invention may transmit a fault flag to the outside in real time using the metadata field (M-field) in the RAS mode. In addition, by transmitting the fault flag bit to multiple metadata in duplicate, a means of defense against errors in the fault flag itself can be provided.

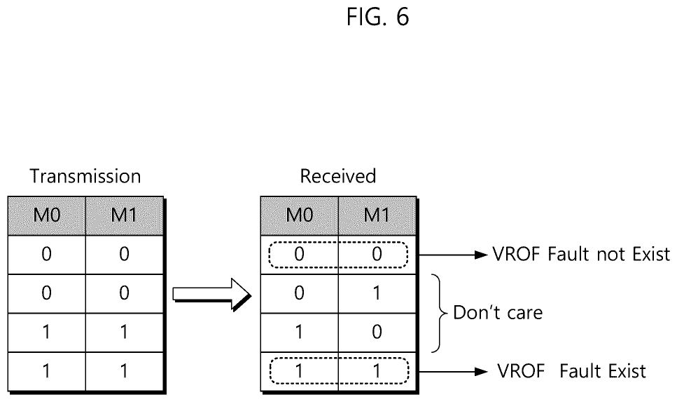

FIG. 6 is a table showing an example of a method of transmitting a fault flag using a metadata field in the RAS mode according to some implementations. In FIG. 6, a memory device (1300, see FIG. 2) can transmit 2-bit metadata M0 and M1 corresponding to a valid read operation flag VROF in the RAS mode with the same bit value (00 or 11). Then, the memory controller 1100 identifies the valid read operation flag VROF using the 2-bit metadata M0 and M1 received in real time.

If the valid read operation flag VROF does not exist, the memory device 1300 will write and transmit the metadata M0 and M1 as ‘00’. Then, the memory controller 1100 will receive ‘00’ as the same metadata M0 and M 1 value in a normal case. If the received metadata M0 and M1 is ‘00’, the memory controller 1100 may determine that the valid read operation flag VROF does not exist.

On the other hand, if the valid read operation flag VROF exists, the memory device 1300 will write and transmit the metadata M0 and M1 as ‘11’. Then, the memory controller 1100 will normally receive ‘11’ as the same metadata M0 and M 1 value. If the received metadata M0 and M1 is ‘11’, the memory controller 1100 determines that the valid read operation flag VROF exists.

In addition, even if the metadata M0 and M1 is written as ‘00’ or ‘11’ and the data DQ packet is transmitted, the metadata M0 and M1 may be received as ‘01’ or ‘10’ due to a channel or link error. In this case, the memory controller 1100 can ignore the valid read operation flag VROF.

As described above, a method of transmitting 2-bit metadata M0 and M1 by repeatedly describing one fault flag in the RAS mode has been described. The memory controller 1100 can process the fault flag as valid only when the repeated bit values are the same bit values (00 or 11).

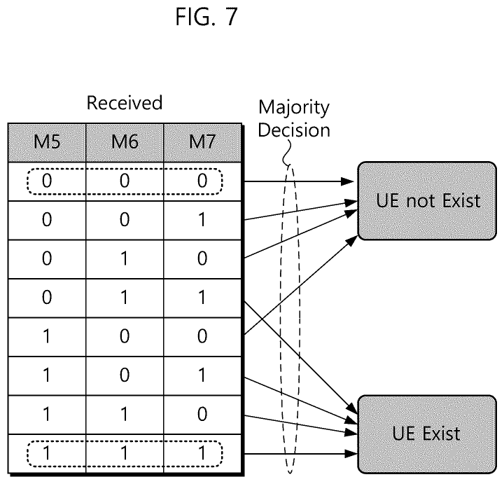

FIG. 7 is a table exemplarily showing a method of processing a fault flag received in the RAS mode according to some implementations. In FIG. 7, the memory device (1300, see FIG. 2) transmits 3-bit metadata M5, M6 and M7 as an OD-ECC UE flag in the RAS mode. At this time, the 3-bit metadata M5, M6 and M7 can be transmitted with the same bit value (‘000’ or ‘111’).

The memory controller 1100 can perform a majority decision on the received 3-bit metadata M5, M6 and M7. If the metadata M5, M6 and M7 transmitted from the memory device 1300 is received as ‘000’, the memory controller 1100 may determine that the OD-ECC UE flag does not exist. In addition, if the metadata M5, M6 and M7 transmitted from the memory device 1300 is received as ‘111’, the memory controller 1100 may determine that the OD-ECC UE flag exists.

On the other hand, if the bit value of the received metadata M5, M6 and M7 has more logical ‘0’ than logical ‘1’, such as ‘001’, ‘010’, and ‘100’, the memory controller 1100 may determine that the OD-ECC UE flag does not exist. In addition, if the bit value of the received metadata M5, M6 and M7 has more logical ‘1’ than logical ‘0’, such as ‘011’, ‘101’, and ‘110’, the memory controller 1100 may determine that the OD-ECC UE flag exists. That is, the memory controller 1100 can identify the OD-ECC UE flag by performing a majority decision on the received metadata M5, M6 and M7.

As described above, the memory device 1300 may transmit by repeatedly writing the same flag value in the metadata bits assigned to each fault flag. And the memory controller 1100 can receive a high-reliability fault flag in real time through majority decision.

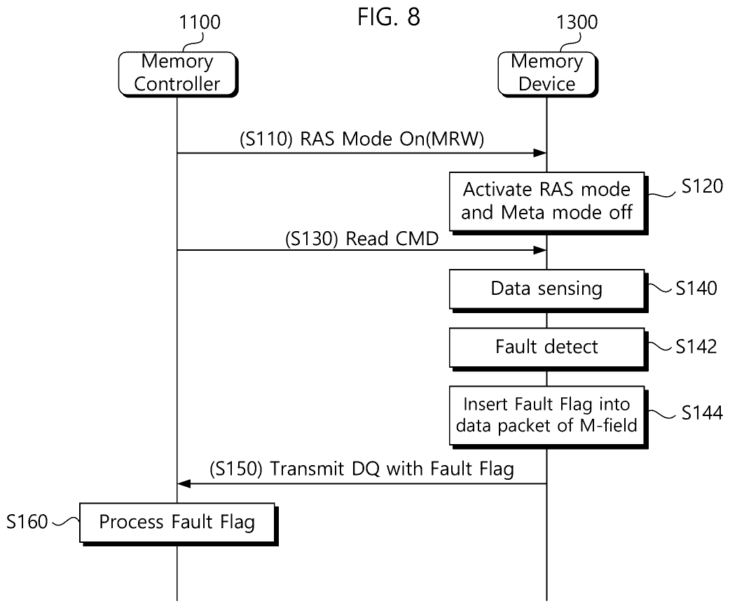

FIG. 8 is a diagram showing an example of a method of setting a RAS mode and transmitting a fault flag in a memory system according to some implementations. In FIG. 8, the memory controller 1100 can activate the RAS mode of the memory device 1300 to receive a real-time fault flag.

In step S110, the memory controller 1100 transmits a mode register write MRW command to the memory device 1300 to set the RAS mode.

In step S120, the memory device 1300 will deactivate the meta mode and activate the RAS mode according to the RAS mode setting request of the memory controller 1100. In the meta mode, the metadata field of the data DQ packet is used for outputting the metadata stored in the memory device 1300. However, when the RAS mode is activated, the metadata field of the data DQ packet is allocated for transmission of the fault flag provided in the fault flag register 1360 of the present invention.

In step S130, the memory controller 1100 may transmit a read command of the memory device 1300.

In step S140, the memory device 1300 senses data of the requested address in response to the read command. The sensed data is configured as a data DQ packet for output from the input/output circuit 1370.

In step S142, the memory device 1300 collects and stores faults for the data DQ packet generated in real time. For example, depending on whether a fault is detected, a VROF, an OD-ECC CE flag, an OD-ECC UE flag, a Link-ECC UE Poison flag, etc. may be generated and stored.

In step S144, the memory device 1300 inserts the fault flag stored in the fault flag register 1360 into the metadata field of the data DQ packet configured in the input/output circuit 1370.

In step S150, the memory device 1300 transmits the data DQ packet into which the generated fault flag is inserted in real time to the memory controller 1100. That is, the fault flag for one data DQ packet may be transmitted in real time as a unit of data DQ packet.

In step S160, the memory controller 1100 processes the received data DQ packet. For example, the memory controller 1100 processes the data of the data field of the data DQ packet as read data, and uses the fault flag received through the metadata field as fault information for the read data. That is, the memory controller 1100 may determine whether the received data packet is valid or not based on the existence and type of the fault flag. In addition, the memory controller 1100 can perform correction processing for correctable errors to restore the data.

As described above, the memory controller 1100 and the memory device 1300 of the present invention may exchange the fault flag of the data DQ packet output through the metadata field of the data DQ packet in real time in the RAS mode.

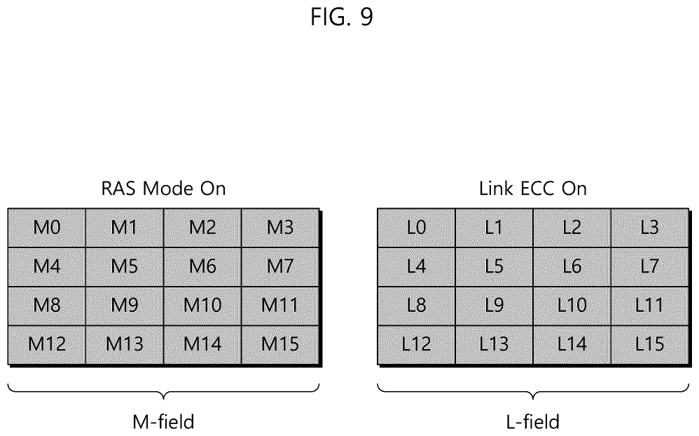

FIG. 9 is a table showing examples of a metadata field (M-field) and a link ECC field (L-field) when the link ECC mode is activated in RAS mode according to some implementations. In FIG. 9, when the link ECC mode is set to the ‘On’ state in the RAS mode, link ECC parity for data DQ packet may be inserted into the link ECC field (L-field).

When the link ECC mode is activated to the ‘On’ state in the RAS mode, a fault flag for data DQ packet generated in real time is assigned to the metadata field (M-field). For example, 16-bit metadata M0 to M15 may be assigned a valid read operation flag VROF, an OD-ECC CE flag, an OD-ECC UE flag, and a Link-ECC UE Poison flag, etc.

In addition, when the link ECC mode is activated in the ‘On’ state in the RAS mode, link ECC parity for the data DQ packet may be inserted into the link ECC field (L-field). That is, link error protection for the entire data DQ packet including metadata M0 to M15 is possible through 16-bit link ECC data L0 to L15.

As described above, the memory device 1300 provides the memory controller 1100 with the fault flag of the data DQ packet output through the metadata field (M-field) of the data DQ packet in real time in the RAS mode. At this time, when the link ECC mode is activated, the memory device 1300 may additionally provide the memory controller 1100 with the link ECC parity for the data DQ packet in the RAS mode.

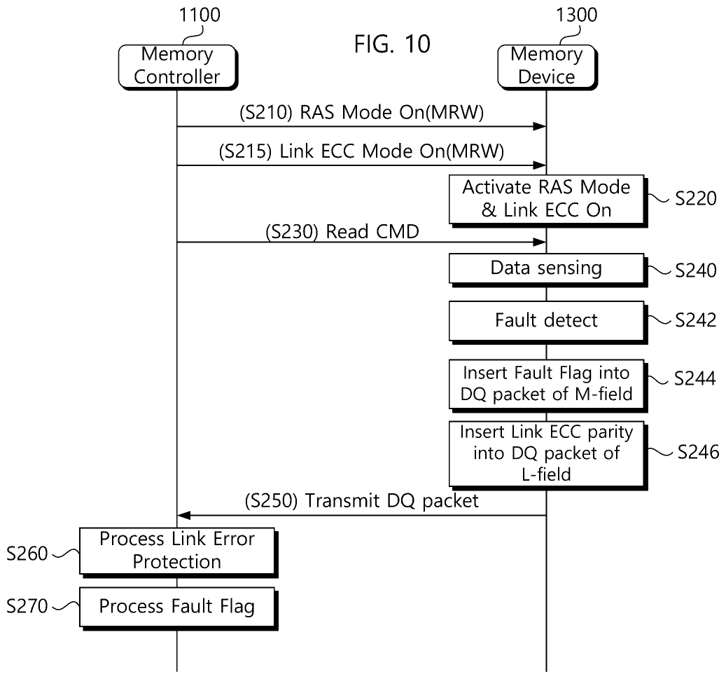

FIG. 10 is a diagram showing an example of a method for setting a RAS mode and transmitting a fault flag in a memory system according to some implementations. In FIG. 10, the memory controller 1100 may activate the RAS mode of the memory device 1300 and activate the link ECC mode to the on state in order to receive a real-time fault flag.

In step S210, the memory controller 1100 transmits a mode register write MRW command to the memory device 1300 for setting the RAS mode.

In step S215, the memory controller 1100 transmits a mode register write MRW command to the memory device 1300 for activating the link ECC mode in the RAS mode state.

In step S220, the memory device 1300 will deactivate the meta mode and activate the RAS mode according to the RAS mode setting request of the memory controller 1100. In addition, the memory controller 1100 activates the link ECC mode to ‘On’ state in the RAS mode activation state. When the RAS mode is activated, the metadata field (M-field) of the data DQ packet is assigned to the fault flag provided in the fault flag register 1360 of the present invention. In addition, when the link ECC mode is switched to ‘On’ state along with the activation of the RAS mode, the link ECC field (L-field) may be assigned a link ECC parity for the data DQ packet.

In step S230, the memory controller 1100 may transmit a read command to the memory device 1300.

In step S240, the memory device 1300 senses data of the requested address from the cell array (1310, see FIG. 2) in response to the read command of the memory controller 1100. The sensed data is configured as a data DQ packet for output from the input/output circuit 1370.

In step S242, the memory device 1300 determines whether there is an fault in the data DQ packet generated in real time. For example, depending on whether the fault is detected, a VROF, an OD-ECC CE flag, an OD-ECC UE flag, a Link-ECC UE Poison flag, etc. may be generated.

In step S244, the memory device 1300 inserts the generated fault flag into the metadata field (M-field) of the data DQ packet configured in the input/output circuit 1370.

In step S246, the memory device 1300 inserts the previously generated link ECC parity into the link ECC field (L-field) of the data DQ packet configured in the input/output circuit 1370. Link ECC parity may include information for error correction or detection for data of a data DQ packet and a fault flag inserted in a metadata field (M-field). Therefore, an error defense function for a fault flag may be additionally provided through link ECC parity.

In step S250, the memory device 1300 transmits the data DQ packet with the fault flag and link ECC parity inserted therein generated in real time to the memory controller 1100. That is, a fault flag and link ECC parity for one data DQ packet may be provided to the memory controller 1100 in real time as a unit of data DQ packet.

In step S260, the memory controller 1100 performs link error processing for the received data DQ packet. For example, the memory controller 1100 may detect or correct a link error by decoding the link ECC parity provided through the link ECC field (L-field) of the data DQ packet. If the link error exists in the fault flag transmitted through the metadata field (M-field), the link error can be detected or corrected through the link ECC parity. That is, the memory controller 1100 may determine whether the received data DQ packet is valid by decoding the link ECC parity. In addition, the memory controller 1100 can perform correction processing for correctable link errors to restore data.

In step S270, the memory controller 1100 processes the fault flag of the received data DQ packet. For example, the memory controller 1100 processes the data of the data field of the data DQ packet as read data, and uses the fault flag received through the metadata field (M-field) as fault information for the read data. The memory controller 1100 may determine whether the received data DQ packet is valid based on the presence and type of the fault flag.

As described above, the memory controller 1100 and the memory device 1300 of the present invention can set the link ECC mode to ‘On’ state in the RAS mode. The memory controller 1100 may receive in real time the fault flag and the link ECC parity output through the metadata field (M-field) and the link ECC field (L-field) of the data DQ packet. Accordingly, both the reception of the real-time fault flag through the RAS mode and the reliability of data transmission through the link ECC function may be secured.

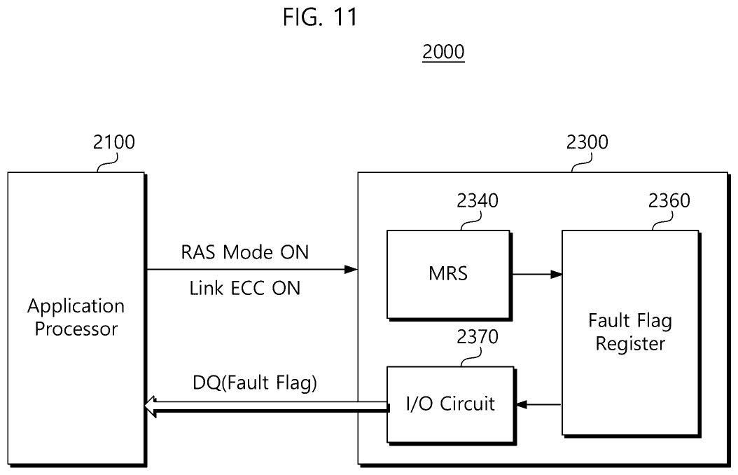

FIG. 11 is a block diagram showing an example of a mobile system according to some implementations. In FIG. 11, the mobile system 2000 may include an application processor 2100 and a memory device 2300.

The application processor 2100 may activate a RAS mode of the memory device 2300 to receive a fault flag in real time. The memory device 2300 may operate in the RAS mode supported for fault detection or data integrity. In addition, various operations for signal integrity for data transmission and communication with the application processor 2100 may be supported in the RAS mode and the link ECC mode.

The application processor 2100 may deactivate the meta mode and activate the RAS mode to receive a fault flag through the metadata field of the data DQ packet. In RAS mode, the application processor 2100 may check in real time whether there is an fault in the output data DQ packet through the fault flag of the metadata field to correct or detect.

The memory device 2300 may change the operation mode such as the meta mode, RAS mode, and link ECC mode according to the control of the application processor 2100. In RAS mode, the memory device 2300 provides the fault flag of the data DQ packet unit output through the metadata field of the data DQ packet to the application processor 2100 in real time. At this time, when the link ECC mode is activated, the memory device 2300 can additionally provide link ECC data for the data packet in RAS mode to the application processor 2100. To this end, the memory device 2300 can include a mode set register 2340, a fault flag register 2360, and an input/output circuit 2370. The mode set register 2340, the fault flag register 2360, and the input/output circuit 2370 may be substantially the same as those of FIG. 1 described above. Accordingly, their descriptions will be omitted. In some implementations, the memory device 2300 may be implemented as an LPDDR6 memory optimized for a mobile environment.

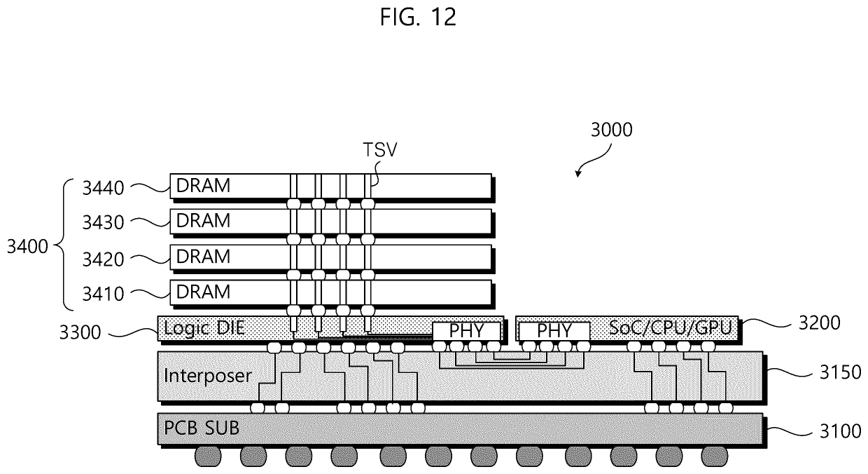

FIG. 12 is a cross-sectional view showing an example of a memory system according to some implementations. In FIG. 12, the memory system 3000 implemented as a stacked semiconductor device may include a high-bandwidth memory 3400 composed of a PCB substrate 3100, an interposer 3150, a processor 3200, a logic die 3300, and a plurality of DRAM dies 3410, 3420, 3430, and 3440.

The memory system 3000 connects a high-bandwidth memory 3400 and a processor 3200 using an interposer 3150. The interposer 3150 is placed on top of the PCB substrate 3100 and is electrically connected to the PCB substrate 3100 through flip chip bumps FBs. The interposer 3150 can connect the logic die 3300 and the processor 3200. The interposer 3150 can connect a physical layer of the logic die 3300 and a physical layer of the processor 3200, and can provide physical paths formed using conductive materials. Accordingly, the logic die 3300 and the processor 3200 can transmit and receive signals to each other through the interposer 3150.

The processor 3200, the logic die 3300, and stacked DRAM dies 3410, 3420, 3430, and 3440 may be placed on the upper portion of the interposer 3150. In order to implement the memory system 3000, through silicon via TSV lines are formed on a plurality of DRAM dies 3410, 3420, 3430, and 3440. The TSV lines may be electrically connected to micro bumps M B formed between the plurality of DRAM dies 3410, 3420, 3430, and 3440.

Although the high-bandwidth memory 3400 is illustrated to include four DRAM dies 3410, 3420, 3430, and 3440, the number of DRAM dies may vary. For example, the high-bandwidth memory 3400 configured in a stacked manner may include eight, twelve, or sixteen HBM dies. The logic die 3300 and the DRAM dies 3410, 3420, 3430, and 3440 may be stacked and electrically connected by the through silicon vias TSVs. For example, the memory system 3000 may be implemented based on the HBM or HM C standard.

In some implementations, the processor 3200 may perform an access operation to write data to the DRAM dies 3410, 3420, 3430, and 3440 or read data stored in the DRAM dies 3410, 3420, 3430, and 3440. The processor 3200 may generate a command CM D and an address A DDR to write data to the DRAM dies 3410, 3420, 3430, and 3440 or to read data stored in the DRAM dies 3410, 3420, 3430, and 3440.

In particular, the processor 3200 may receive a fault flag from the DRAM dies 3410, 3420, 3430, and 3440 in real time by activating the RAS mode of each of the DRAM dies 3410, 3420, 3430, and 3440. The DRAM dies 3410, 3420, 3430, and 3440 may operate in a meta mode for performing initialization, setup, register configuration, training procedures, etc. In some implementations, the DRAM dies 3410, 3420, 3430, and 3440 may operate in RAS mode supported for error detection or data integrity. In addition, the DRAM dies 3410, 3420, 3430, and 3440 support all operations for signal integrity for data transmission and communication with the processor 3200 in the link ECC mode.

The processor 3200 may deactivate the meta mode of the DRAM dies 3410, 3420, 3430, and 3440 and activate the RAS mode to receive a fault flag through the metadata field of the data DQ packet. The metadata field of the data DQ packet provided in the RAS mode includes fault information for one channel data DQ packet. Accordingly, in RAS mode, the processor 3200 can check in real time, and correct or detect the presence of faults in channel data DQ packet output from DRAM dies 3410, 3420, 3430, and 3440 through the metadata field.

Each of the DRAM dies 3410, 3420, 3430, and 3440 can change the operation mode, such as the meta mode, RAS mode, link ECC mode, etc., according to the control of the processor 3200. Each of the DRAM dies 3410, 3420, 3430, and 3440 may provide metadata to the processor 3200 through the metadata field of the data DQ packet in the meta mode. On the other hand, each of the DRAM dies 3410, 3420, 3430, and 3440 may provide a fault flag of a data DQ packet unit output through a metadata field of the data DQ packet in real time to the processor 3200 in the RAS mode. At this time, when the link ECC mode is activated, each of the DRAM dies 3410, 3420, 3430, and 3440 can additionally provide link ECC data for the data DQ packet in the RAS mode to the processor 3200. That is, each of the plurality of DRAM dies 3410, 3420, 3430, and 3440 may operate substantially the same as the memory device 1300 of FIG. 1.

While this disclosure contains many specific implementation details, these should not be construed as limitations on the scope of what may be claimed, equivalents thereof, as well as claims to be described later. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A method for providing a fault flag of a semiconductor memory device, comprising:
changing an operation mode of the semiconductor memory device from a meta mode to a Reliability, Availability and Serviceability (RAS) mode;
storing a fault flag of the semiconductor memory device;
inserting the fault flag into a metadata field of a data packet of the semiconductor memory device; and
outputting the data packet.

2. The method of claim 1, wherein the fault flag includes at least one of a valid read operation flag, an On Die Error Correcting Code Correctable Error flag, an On Die Error Correction Code Uncorrectable Error flag, or a Link-Error Correction Code Uncorrectable Error Poison flag.

3. The method of claim 1, wherein inserting the fault flag into the metadata field comprises repeatedly writing a bit value.

4. The method of claim 3, comprising identifying the fault flag by a majority decision method for the repeatedly written bit value.

5. The method of claim 1, comprising activating a link Error Correcting Code (ECC) mode in the semiconductor memory device in the RAS mode.

6. The method of claim 5, comprising generating a link ECC parity in the semiconductor memory device.

7. The method of claim 6, comprising inserting the link ECC parity into a link ECC field of the data packet.

8. The method of claim 7, comprising detecting or correcting a fault using the fault flag or the link ECC parity.

9. A semiconductor memory device comprising:
a memory cell array configured to store data;
a mode register set configurable to be in a meta mode or a Reliability, Availability, Serviceability (RAS) mode;
a fault flag register configured to store a fault flag generated in the semiconductor memory device;
a mode controller configured to assign the fault flag to a metadata field of a data packet output according to the RAS mode; and
an input/output circuit configured to output the data packet with the fault flag inserted in the metadata field.

10. The device of claim 9, wherein the mode controller is configured to repeatedly write the fault flag in the metadata field.

11. The device of claim 9, wherein the fault flag includes at least one of a valid read operation flag, an On Die Error Correcting Code Correctable Error flag, an On Die Error Correcting Code Uncorrectable Error flag, or a Link-Error Correcting Code Uncorrectable Error Poison flag.

12. The device of claim 9, wherein the mode controller is configured to activate generation of a link Error Correcting Code (ECC) parity when a link ECC mode is activated in the RAS mode state.

13. The device of claim 12, wherein the mode controller is configured to allocate the link ECC parity to the link ECC field of the data packet in response to activation of the link ECC mode.

14. The device of claim 13, wherein the link ECC parity includes the fault flag and at least one of link error detection information or correction information of the data packet.

15. A method for providing a fault flag of a semiconductor memory device, comprising:
activating, by a memory controller, a Reliability, Availability and Serviceability (RAS) mode of the semiconductor memory device;
activating, by a memory controller, a link Error Correcting Code (ECC) mode of the semiconductor memory device;
generating, by the semiconductor memory device, a fault flag and link ECC parity in response to the activation of the RAS mode and the link ECC mode, respectively;
inserting the fault flag into a metadata field of a data packet of the semiconductor memory device; and
inserting the link ECC parity into a link ECC field of the data packet.

16. The method of claim 15, further comprising outputting, to the memory controller, the data packet in which the fault flag and the link ECC parity are inserted.

17. The method of claim 15, comprising detecting or correcting a link error of the fault flag and the data packet based on the link ECC parity.

18. The method of claim 17, wherein inserting the fault flag into a metadata field comprises repeatedly writing the fault flag in the metadata field.

19. The method of claim 18, comprising identifying, by the memory controller, the fault flag by applying a majority decision operation to the metadata field of the received data packet.

20. The method of claim 19, comprising performing, by the memory controller, a link error detection or correction operation on the link ECC field of the received data packet.
